(19) United States
(12) Patent Application Publication
(10) Pub. No.: US 2012/0013358 A1
(43) Pub. Date: Jan. 19, 2012

(54) PROBING APPARATUS FOR INTEGRATED CIRCUIT TESTING

(76) Inventor: Cheng-Yi WANG, Taipei City (TW)

(21) Appl. No.: 12/836,241

(22) Filed: Jul. 14, 2010

(51) Int. Cl. G01R 1/06

(52) U.S. Cl. 324/755.01

(57) ABSTRACT

A probing apparatus for integrated circuit testing at least includes a substrate, a probe body and a bypass capacitor. The substrate is fixed in an external conductor after an internal conductor is filled with an insulating material. One end of the substrate has a section, so that both the internal conductor and the insulating material are exposed on the section. One end of the probe body is electrically connected to the internal conductor exposed on the section. A tip end of the probe body is used for contacting a pad of an element to be tested. The bypass capacitor has a first electrode terminal and a second electrode terminal. The first electrode terminal is electrically connected to the probe body, and the second electrode terminal is connected to the external conductor at the end of the substrate.

### BACKGROUND OF THE INVENTION

1. Field of the Invention

The present invention relates to a probing apparatus for integrated circuit testing that can effectively filter out alternating current (AC) noise of a power supply or ground point.

2. Related Art

In the field of integrated circuit testing, a probe part is an interface between a signal transmission line of test head and device under test in an integrated circuit. The device under test in the integrated circuit may be a die in a semiconductor wafer, and a solder pad that can be probed by a probe is formed on a surface of the die.

Generally speaking, a probe set has a plurality of probes. When a pad on a semiconductor die to be tested is electrically contacted, the electrical characteristics of the integrated circuit thereof can be tested, and thus it can be determined whether the semiconductor die is good. For good semiconductor dies, the subsequent packaging or assembly process will be carried out. Bad semiconductor dies will be discarded or repaired, so as not to incur any additional package cost. However, during the signal transmission of an integrated circuit test, besides the need of connecting high-frequency signals, an additional direct current (DC) bias power supply is often required. The DC bias power supply is interfered by the noise caused by the combination of the conducted high-frequency switching current and the inductance (L·di/dt) of the probe itself and coupled to a power supply or ground point, which leads to signal distortion, thus resulting in that the electrical characteristics of the semiconductor die cannot be accurately measured.

Therefore, referring to FIG. 3, U.S. Pat. No. 4,764,723 discloses a probe having low-impedance transmission lines that is fabricated by using an alumina substrate, so as to supply a steady DC bias power supply to an integrated circuit. Although the probe includes a capacitor c, the front end of the substrate configured with the capacitor c needs to be reduced to chip-scale, thus resulting in a complex manufacturing process, a high cost, and unsuitability for mass production.

In addition, referring to FIG. 4, U.S. Pat. No. 5,373,231 also discloses a probing apparatus having an attached bypass capacitor. The probing apparatus includes a radio frequency (RF) probe a, a wire probe b, and a capacitor c disposed between the RF probe and the wire probe. The coaxial probe a and the wire probe b are directly mounted on a probe card. The capacitor c flexibly interconnects the coaxial probe a and the wire probe b in a mechanical manner, so as to effectively reduce AC noise and ensure the accuracy of test results. Since the attached capacitor must be disposed between each two probes, the cost is high and the manufacturing process is time-consuming. Although it is suitable for the connection and configuration of cantilever probes, if the heights of the pads of the element to be tested are different, the two probes will interfere with and restrain each other, and thus the test result is not desirable. Furthermore, the wire probe b is not well shielded, so that the coupled noise cannot be isolated completely.

Therefore, the present invention is made by the inventor through continuous research, development and improvement.

### SUMMARY OF THE INVENTION

Accordingly, the present invention is mainly directed to a probing apparatus for integrated circuit testing that can effectively filter out AC noise of a power supply or ground point.

In order to achieve the above objectives, the present invention provides a probing apparatus for integrated circuit testing. The probing apparatus at least includes a substrate, a probe body and a bypass capacitor. The substrate is fixed in an external conductor after an internal conductor is filled with an insulating material. One end of the substrate has a section, so that both the internal conductor and the insulating material are exposed on the section. One end of the probe body is electrically connected to the internal conductor exposed on the section. A tip end of the probe body is used for contacting a pad of an element to be tested. The bypass capacitor has a first electrode terminal and a second electrode terminal. The first electrode terminal is electrically connected to the probe body, and the second electrode terminal is connected to the external conductor at the end of the substrate.

In the implementation, the substrate is a coaxial transmission line structure.

In the implementation, the insulating material is made of polyamide.

In the implementation, the bypass capacitor is attached on the insulating material exposed on the section.

In the implementation, the insulating material exposed on the section at the end of the substrate protrudes from the section at the end of the substrate, so that the bypass capacitor is attached and fixed on the insulating material protruding from the section at the end of the substrate.

In order to make the present invention more comprehensible, the present invention is described in detail below through an embodiment.

### BRIEF DESCRIPTION OF THE DRAWINGS

The present invention will become more fully understood from the detailed description given herein below for illustration only, and thus are not limitative of the present invention, and wherein:

FIG. 1 is a three-dimensional schematic outside view of a probing apparatus mounted on a probe card according to an embodiment of the present invention;

FIG. 2A is a schematic outside view of a bypass capacitor attached on an probe according to an embodiment of the present invention;

FIG. 2B is a schematic outside view of a bypass capacitor attached on an insulating material according to an embodiment of the present invention;

FIG. 2C is a schematic outside view of a bypass capacitor attached on an insulating material protruding from a section of a substrate according to an embodiment of the present invention;

FIG. 3 is a schematic structural view of U.S. Pat. No. 4,764,723 in the prior art; and

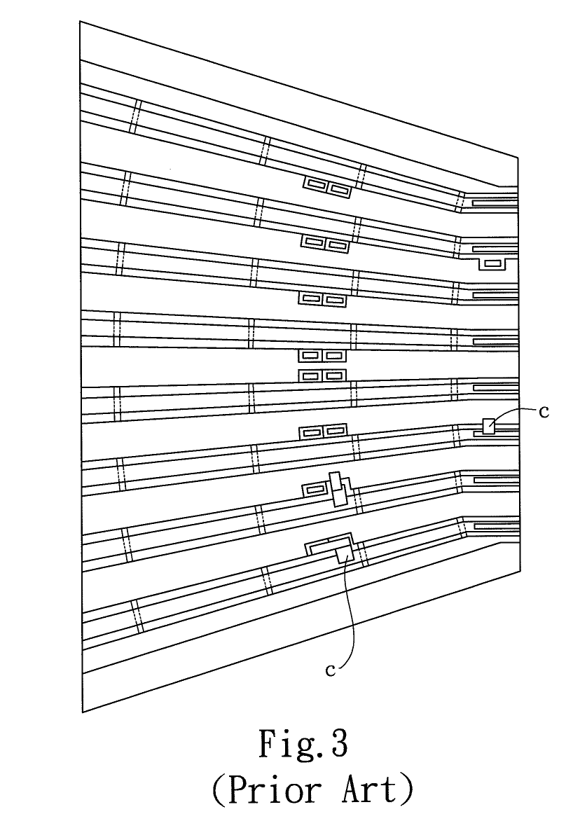

FIG. 4 is a schematic structural view of U.S. Pat. No. 5,373,231 in the prior art.

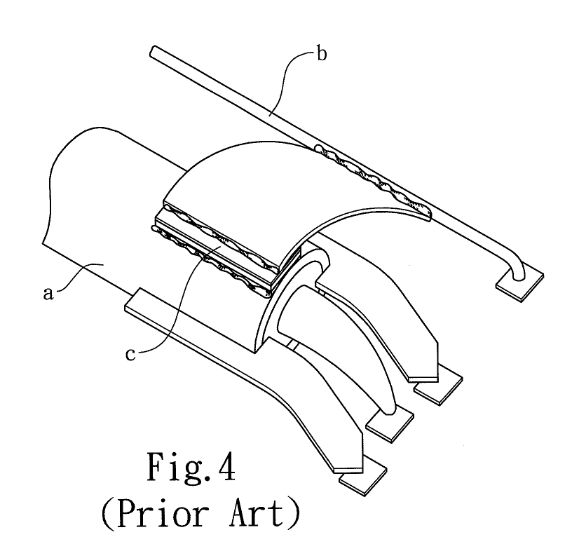

### DETAILED DESCRIPTION OF THE INVENTION

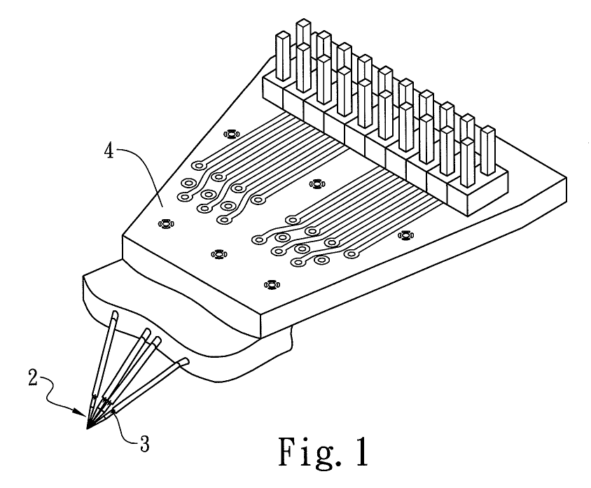

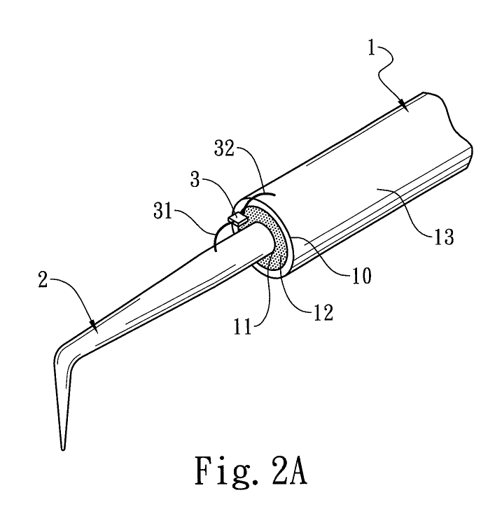

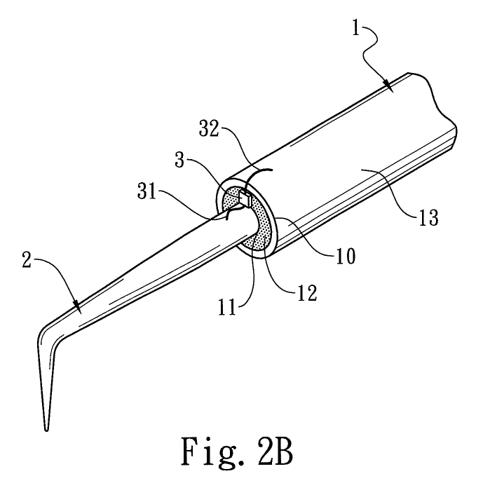

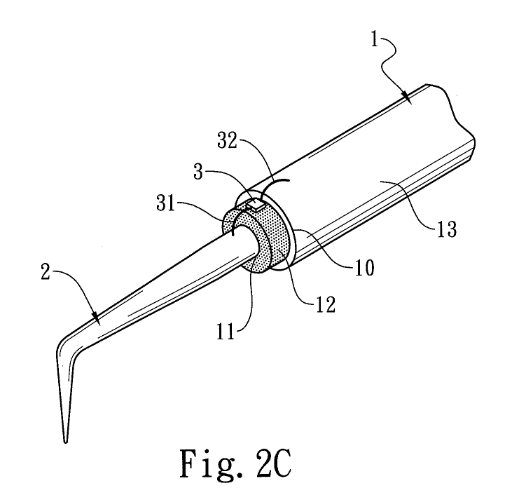

FIG. 1 and FIG. 2A show an embodiment of a probing apparatus for integrated circuit testing according to the present invention. The probing apparatus at least includes a substrate 1, a probe body 2 and a bypass capacitor 3.

The substrate 1 may be a coaxial cable structure or other transmission line structures. The substrate 1 is fixed in an external conductor 13 after an internal conductor 11 is filled with an insulating material 12. The insulating material 12 is made of polyamide. One end of the substrate 1 has a section 10, so that both the internal conductor 11 and the insulating material 12 are exposed on the section 10. One end of the probe body 2 is electrically connected to the internal conductor 11 exposed on the section 10. A tip end of the probe body 2 is used for contacting a pad of an element to be tested. The bypass capacitor 3 has a first electrode terminal 31 and a second electrode terminal 32. The first electrode terminal 31 is electrically connected to the probe body 2, and the second electrode terminal 32 is connected to the external conductor 13 at the end of the substrate. Therefore, after the probing apparatus for integrated circuit testing of the present invention is mounted on a probe card 4, the tip end of the probe 2 contacts the pad of the element to be tested during measurement, and since the bypass capacitor 3 is directly connected between the probe body 2 and the external conductor 13 of the substrate 1, the external conductor 13 forms a ground terminal, so that AC noise of a power supply or ground point caused by the conducted high-frequency switching current is directly filtered out through the bypass capacitor 3. Furthermore, the external conductor 13 of the substrate 1 can also form an effective shield, and the impedance of the probe body 2 can be reduced by controlling the thickness of the insulating material 12, thus achieving the decoupling objective.

In the implementation, the bypass capacitor 3 provided by the present invention may be attached on the insulating material 12 exposed on the section 10 (as shown in FIG. 2B). Alternatively, the insulating material 12 exposed on the section 10 at the end of the substrate 1 protrudes from the section 10 at the end of the substrate 1, so that the bypass capacitor 3 is attached and fixed on the insulating material 12 protruding from the section 10 at the end of the substrate 1 (as shown in FIG. 2C).

Therefore, the present invention has the following advantages.

1. In the present invention, a bypass capacitor is directly connected between a probe body and an external conductor (ground terminal) of a substrate, that is, each probe body independently has a bypass capacitor, so that during measurement, the probe body is not affected by the different heights of solder pads of an element to be tested, or restrained by other cantilever probe bodies.

2. The bypass capacitor provided by the present invention is directly connected between the probe body and the external conductor at the end of the substrate, so that the bypass capacitor is nearer to the element to be tested, and the effectiveness of the bypass capacitor is improved effectively, thus filtering out the AC noise of the power supply or ground point more effectively.

3. The external conductor of the substrate provided by the present invention can form an effective shield, and the impedance of the probe body can be reduced by controlling the thickness of the insulating material, thus achieving the decoupling objective.

While the present invention has been described with reference to the embodiments and technical means thereof, various changes and modifications can be made based on the disclosure or teachings described herein. Any equivalent changes made based on the concepts of the present invention having their effect without departing from the spirit encompassed by the specification and drawings should be construed as falling within the scope of the present invention as defined by the appended claims.

According to the aforementioned disclosure, the present invention surely can achieve the expected objectives to provide a probing apparatus for integrated circuit testing that can effectively eliminate high-frequency reflected waves or filter out AC noise of a power supply or ground point, which has industrial applicability. Thus, the application for a patent is filed according to the law.

What is claimed is:

1. A probing apparatus for integrated circuit testing, at least comprising:
a substrate, fixed in an external conductor after an internal conductor is filled with an insulating material, wherein one end of the substrate has a section, so that both the internal conductor and the insulating material are exposed on the section;
a probe body, wherein one end of the probe body is electrically connected to the internal conductor exposed on the section, a tip end of the probe body is used for contacting a pad of an element to be tested; and
a bypass capacitor, having a first electrode terminal and a second electrode terminal, wherein the first electrode terminal is electrically connected to the probe body, and the second electrode terminal is connected to the external conductor at the end of the substrate.

2. The probing apparatus for integrated circuit testing according to claim 1, wherein the substrate is a coaxial transmission line structure.

3. The probing apparatus for integrated circuit testing according to claim 1, wherein the insulating material is made of polyamide.

4. The probing apparatus for integrated circuit testing according to claim 1, wherein the bypass capacitor is attached on the insulating material exposed on the section.

5. The probing apparatus for integrated circuit testing according to claim 4, wherein the insulating material exposed on the section at the end of the substrate protrudes from the section at the end of the substrate, so that the bypass capacitor is attached and fixed on the insulating material protruding from the section at the end of the substrate.
